(19) United States
(12) Patent Application Publication
(10) Pub. No.: US 2026/0040533 A1
(43) Pub. Date: Feb. 5, 2026

(54) MEMORY DEVICES WITH WEAVED DIGIT LINES

(71) Applicant: Micron Technology, Inc., Boise, ID (US)

(72) Inventor: Russell Allen Benson, Boise, ID (US)

(21) Appl. No.: 19/265,499

(22) Filed: Jul. 10, 2025

Related U.S. Application Data
(60) Provisional application No. 63/677,858, filed on Jul. 31, 2024.

(51) Int. Cl. H10B 12/00

(52) U.S. Cl. CPC H10B 12/482; H10B 12/02

(57) ABSTRACT

A variety of applications can include an apparatus having a memory device, where the memory device includes weaved digit lines coupled to memory cells of the memory device. The weaved digit lines can be constructed as metal lines having localized widenings about digit line contacts to which the metal lines are coupled. In some examples, access lines can be constructed having localized widenings about gates of access transistors of memory cells of a memory device.

### PRIORITY APPLICATION

This application claims the benefit of priority to U.S. Provisional Application Ser. No. 63/677,858, filed Jul. 31, 2024, which is incorporated herein by reference in its entirety.

### FIELD OF THE DISCLOSURE

Embodiments of the disclosure relate generally to electronic devices and systems, and more specifically, to memory devices, components of memory devices, and formation thereof.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others. Properties of memory devices can be improved by enhancements to the design and fabrication of components of the memory devices.

### BRIEF DESCRIPTION OF THE DRAWINGS

The drawings, which are not necessarily drawn to scale, illustrate generally, by way of example, but not by way of limitation, various embodiments discussed in the present document.

FIGS. 1-2 illustrate an example subtractive process flow for forming digit lines in a memory device, in accordance with various embodiments.

FIGS. 3-5 illustrate an example damascene process flow for forming digit lines in a memory device, in accordance with various embodiments.

FIGS. 6-7 illustrate spatial relationships of digit line contacts and cell contacts in a structure having a pattern of openings for straight digit lines.

FIG. 8 shows an example structure having digit line contacts and cell contacts with openings for digit lines structured as straight lines having localized widenings, in accordance with various embodiments.

FIG. 9 illustrates an example structure having digit lines in which the digit lines have bubbles about digit line contacts, in accordance with various embodiments.

FIG. 10 is a flow diagram of features of an example method of forming a memory device, in accordance with various embodiments.

FIG. 11 illustrates an example structure in a process flow to generate a bubble pattern for digit lines of a memory device, in accordance with various embodiments.

FIGS. 12-15 illustrate an example process flow to generate a bubble pattern for digit lines of a memory device, in accordance with various embodiments.

FIGS. 16-18 illustrate an example process flow to generate a bubble pattern for digit lines of a memory device, in accordance with various embodiments.

FIG. 19 is a representation of a memory device including digit lines having localized widening over digit line contacts to memory cells in an array of the memory device, in accordance with various embodiments.

FIGS. 20-22 illustrate three configurations of access lines for a memory device.

FIG. 23 illustrates a structure including a configuration of access lines having localized widenings over gate contacts with respect to active areas, in accordance with various embodiments.

FIG. 24 is a schematic of an example dynamic random-access memory device that can include an architecture with digit lines having localized widening, in accordance with various embodiments.

FIG. 25 is a block diagram illustrating an example of a machine upon which one or more embodiments of one or more memory components may be implemented, in accordance with various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments may be utilized, and structural, logical, mechanical, and electrical changes may be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

With scaling of memory array dimensions, resistance of digit lines (DLs) that transfer data, for example bit lines, can become critical for read/write operations. Associated with the DL resistance in a DRAM device is the resistance of cell contacts, which can be referred to herein as a CCONs, and the resistance of DL contacts. A DL contact couples a DL to a drain/source of an access transistor of a memory cell of the DRAM. A CCON couples a capacitor of the memory cell to the other drain/source of the access transistor. A critical dimension (CD) of a DL can be the width of the DL that is coupled to multiple memory cells. The CD of a DL in relation to a DL contact and CCONs can have varying effects on the resistances of the DL, CCONs, and DL contact, when using a standard DL line structured with a constant uniform width in its arrangement. In addition, for the same DL CD and metal thickness, processing techniques used in the formation of the DLs can be also affect the resistance of the DLs.

The formation of DLs can be accomplished using different processing techniques. One processing technique is a substrative process flow. A subtractive process flow can include the formation of a stack of materials or other multiple material arrangements and the removal of portions of the materials to provide a desired structure having a composition including portions of the original materials. Another processing technique is a damascene process flow. A damascene process flow can include etching line features and via features in a dielectric and then filling those features with metal. The damascene method can include performing a pattern operation prior to etching and also filing the features with barrier metals for the metal. A dual-damascene process can include patterning vias and trenches, in such that metal formation fills the vias and trenches at the same time.

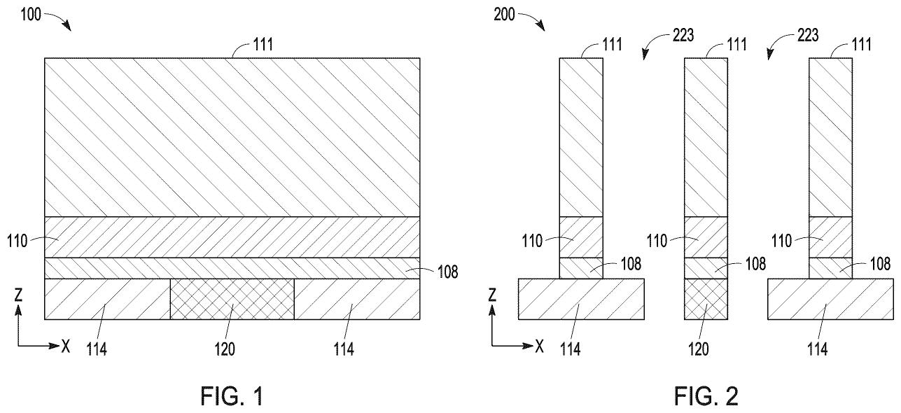

FIGS. 1-2 illustrate an embodiment of an example subtractive process flow for forming DLs in a memory device, such as a DRAM. FIG. 1 is a cross-sectional view of an embodiment of an example structure 100 having been formed with layers of material formed on a starting platform in a substrate. A planar stack of metal has been formed by an appropriate fabrication process. With the cross-sectional view in the x-z plane, the materials extend in the y-direction. A barrier metal 108 has been formed on and extending along surfaces of a dielectric 114 in which a DL contact 120 has been formed. A DL metal 110 has been formed on barrier metal 108 and a capping dielectric 111 has been formed on DL metal 110. Metals for structure 100 can be formed using a number of different process techniques such as, but not limited to, one or more of physical vapor deposition (PVD), chemical vapor deposition (CVD), plasma-enhance chemical vapor deposition (PECVD), or atomic layer deposition (ALD) deposition. PVD schemes can include more metal selections than other schemes, as PVD approaches are available as a planar deposition that typically provides lowest resistance. Metals for DL metal 110 can include, but are not limited to, one or more of tungsten (W), molybdenum (Mo), and ruthenium (Ru). Barrier metal 108 can include, but is not limited to, one or more of titanium (Ti), titanium nitride (TiN_{X}), tungsten nitride (WN), tungsten silicide (WSi_{X}), or tungsten silicide nitride (TiSi_{X}N_{y}). DL contact 120 can be realized by, but is not limited to, a silicon column. Dielectric 114 can be, but is not limited to, silicon oxide (SO_{X}) and cap dielectric 111 can be, but is not limited to, a silicon nitride (SiN_{X}) or silicon oxycarbide SiO_{X}C_{Y}.

FIG. 2 is a cross-sectional view of an embodiment of an example structure 200 after processing structure 100 of FIG. 1 in the subtractive process flow. Material has been removed from each region of structure 100 shown in FIG. 1. The removal can be made by an appropriate substrative etch. Three DL structures have been formed, where each DL structure has DL metal 110 on and contacting barrier metal 108 with cap dielectric 111 covering DL metal. Openings 223 created by the material removal separates the three DL structures from each other. In this cross-sectional view, the middle DL structure is on and contacting the remaining DL contact 120. The other two DL structures are on and contacting respective DL contacts in planes different from the plane of the cross-sectional view of FIG. 2. Though three DL structures are shown, the formation of DL lines using the subtraction flow process can be implemented for significantly more DL lines.

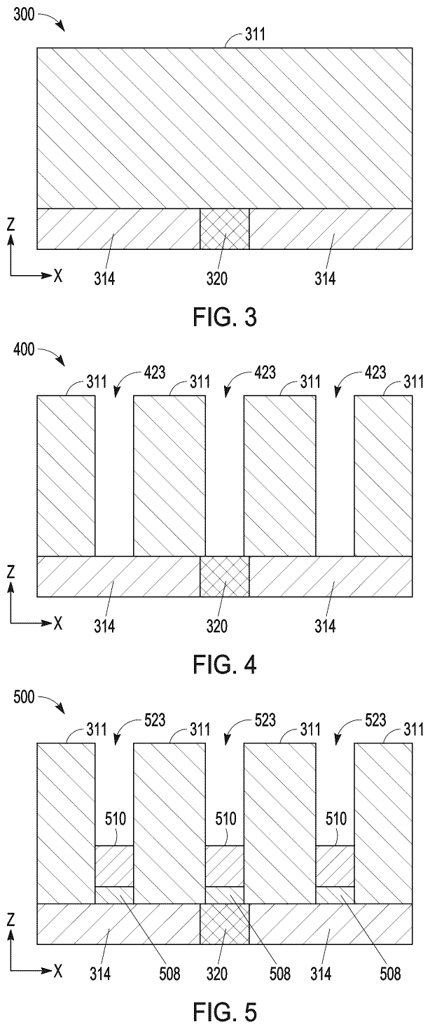

FIGS. 3-5 illustrate an embodiment of an example damascene process flow for forming DLs in a memory device, such as a DRAM. FIG. 3 is a cross-sectional view of an embodiment of an example structure 300 having been formed with material formed on a starting platform in a substrate. With the cross-sectional view in the x-z plane, the materials extend in the y-direction. Only a planar dielectric formation has been made. A dielectric 311 has been formed on and extending along surfaces of a dielectric 314 in which a DL contact 320 has been formed. Dielectric 311 can be formed by a planar dielectric process. Dielectric 314 can be, but is not limited to, silicon oxide (SO_{X}) and dielectric 311 can be, but is not limited to, a SiN_{X} or SiO_{X}C_{Y}. DL contact 320 can be realized by, but is not limited to, a silicon column.

FIG. 4 is a cross-sectional view of an embodiment of an example structure 400 after processing structure 300 of FIG. 3 in the damascene process flow. Material has been removed from portions of dielectric 311, forming openings 423 to top surfaces of dielectric 314 in which a DL contact 320. The removal can be made by an appropriate damascene etch.

FIG. 5 is a cross-sectional view of an embodiment of an example structure 500 after processing structure 400 of FIG. 4 in the damascene process flow. Three DL structures have been formed, where each DL structure has DL metal 510 on and contacting barrier metal 508. In the damascene process flow, portions of originally formed dielectric 311 separate the three DL structures from each other. In this cross-sectional view, the middle DL structure is on and contacting the remaining DL contact 320. The other two DL structures are on and contacting respective DL contacts in planes different from the plane of the cross-sectional view of FIG. 5. The formation of the DL structures has reduced openings 423 of structure 400 of FIG. 4, forming openings 523, which can be used for further processing. Though three DL structures are shown, the formation of DL lines using the damascene flow process can be implemented for significantly more DL lines.

Metals for structure 500 can be formed using a number of different process techniques such as, but not limited to, one or more of CVD, PECVD, or ALD deposition. Damascene flow limits metal deposition options as metal is provided to fill in openings (trenches) 423, which are non-PVD processes. Metals for DL metal 310 can include, but are not limited to, one or more of W, Mo, or Ru. Barrier metal 308 can include, but is not limited to, one or more of Ti, TiN_{X}, WN, WSi_{X}, or TiSi_{X}N_{y}. For the same DL CD and metal thickness, damascene flow, compared to other process flows, may have highest DL resistance.

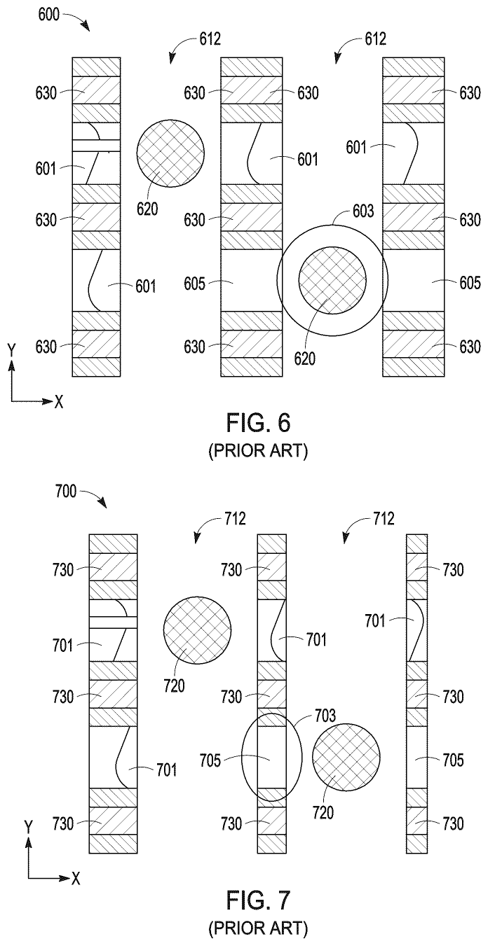

FIGS. 6-7 illustrate spatial relationships of DL contacts and CCONs in a structure having a pattern of openings for straight DLs. FIG. 6 shows a structure 600 having DL contacts and CCONs for a minimum damascene DL CD. Straight line openings 612 for DLs are arranged over DL contacts 620. DL contacts 620 are shown relative to access lines (WLs) 630, active areas 601, and CCONs 605. Region 603 indicates that when DL has its minimum width, DLs in straight line openings 612 may not completely overlap DL contacts 620. In this configuration with a minimum width, CCONs 605 can have their lowest resistance range, the resistances of the DLs can be at their highest range, and the resistances of the DL contacts 620 can be their highest range.

FIG. 7 shows a structure 700 having DL contacts and CCONs for a maximum damascene DL CD. Straight line openings 712 for DLs are arranged over DL contacts 720. DL contacts 720 are shown relative to WLs 730, active areas 701, and CCONs 705. Region 703 indicates that when DL has its maximum width, CCONs are at smallest dimensions for CCONS. In this configuration with a maximum width, CCONs 705 can have their highest resistance range, the resistances of the DLs can be at their lowest range, and the resistances of the DL contacts 620 can be at their lowest range.

In various embodiments, weaved DLs can be used in memory devices to enhance the resistance properties associated with DLs. The weaved DLs can be constructed as metal lines having localized widenings about DL contacts to which the metal lines are coupled. The metal lines can be constructed as straight lines having a constant width except at the location of the localized widenings. The pattern of localized widenings of a DL can be configured as bubbles along the path of the digit line. A bubble, as used herein, is a structure having a bubble-like shape. The amount of bubble relative to the uniform sections of the DLs can be used to optimize all or portions of the resistances of the DLs, DL contacts, and CCONs.

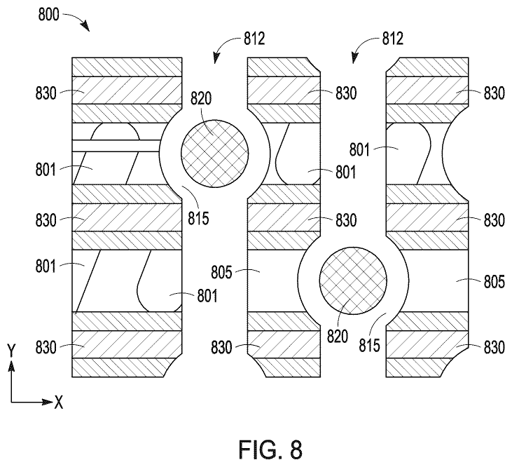

FIG. 8 shows an embodiment of an example structure 800 having DL contacts 820 and CCONs 805 with openings for DLs structured as straight lines having localized widenings 815. The localized widenings 815 can be located above and about DL contacts 820. DL contacts 820 are shown relative to WLs 830, active areas 801, and CCONs 805. By selecting the appropriate bubble amount, resistance of each the DLs, DL contacts 820, and CCONs 805 can be optimized. The optimizations of these parameters can be based on simulations of the bubble pattern of structure 800 and associated materials.

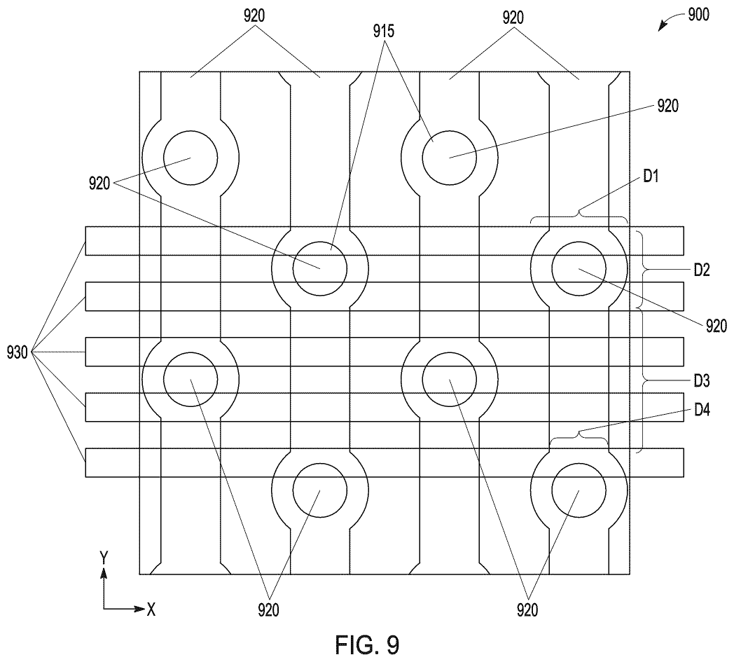

FIG. 9 illustrates an embodiment of an example structure 900 having DLs 910 and WLs 930 in which DLs 910 have bubbles 915, which are examples of localized widenings, about regions 920 for DL contacts in dielectric material 911 of a DL damascene trench. Relative arrangement of DLs 910 and WLs 930 is shown, where DLs 910 and WLs 930 are on different planes and do not intersect. In FIG. 9, D1 is the CD (width) of bubble 915 of DLs 910 and D2 is the length of bubble 915 along the direction of the uniform sections of a DL 910. D1 can be, but is not limited to, the range of 10 nm to 25 nm. D2 can be, but is not limited to, the range of 10 nm to 30 nm. D3 is the length of a DL 910 between directly adjacent bubbles 915 along the direction of DL 910. D3 can be, but is not limited to, a range of 70 nm to 90 nm. D4 is the CD of DL 910 between directly adjacent bubbles 915 along the direction of DL 910. D4 can be, but is not limited to, a range of 5 nm to 15 nm.

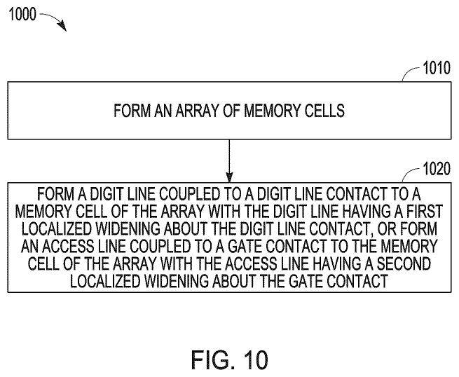

FIG. 10 is a flow diagram of features of an embodiment of a method 1000 of forming a memory device. At 1010, an array of memory cells is formed. At 1020, a DL is formed coupled to a DL contact to a memory cell of the array with the DL having a first localized widening about the DL contact. In addition to or alternatively, an WL is formed coupled to a gate contact to the memory cell of the array with the WL having a second localized widening about the gate contact. The first localized widening and the second localized widening may or may not have the same widening distance.

Variations of method 1000 or methods similar to method 1000 can include a number of different embodiments that may be combined depending on the application of such methods or the architecture or process flow of an integrated circuit for which such methods are implemented. Such methods can include forming the first localized widening by direct printing a dielectric material with a pattern of open lines having localized widenings in each open line spaced apart in the respective open line. Herein, an open line is an opening having the shape of a line. The localized widenings can be made at locations of DL contacts to active areas with the localized widenings extending beyond the boundaries of the contacts. The patterned open lines with localized widenings can be filled with metal for DLs to the memory cells. The localized widenings can be filled with the metal to metal barriers to the contacts. Similarly or alternatively, direct processing of open lines can be performed with localized widenings made at locations of contacts to gates of transistors with the localized widenings extending beyond the boundaries of the contacts. The patterned open lines with localized widenings can be filled with polysilicon for WLs to the memory cells.

Variations can include forming the first localized widening by forming a pattern of first dielectric lines spaced apart from each other and forming a pattern of second dielectric lines on the pattern of first dielectric lines, where the second dielectric lines are also spaced apart from each other. The spaced apart distance of the second dielectric lines can be different from the spaced apart distance of the first dielectric lines. The width of the second dielectric lines can be different from the width of the first dielectric lines. The second dielectric lines can be removed such that spaces between the first dielectric lines have localized widenings along the first dielectric lines. The localized widenings can be made at locations of DL contacts to active areas with the localized widenings extending beyond the boundaries of the DL contacts. The spaces can be filled with metal for DLs to the memory cells. Similarly or alternatively, forming a pattern of dielectric lines on another pattern of dielectric lines and removing the top dielectric lines can be performed to generate spaces with localized widenings of the spaces made at locations of contacts to gates of transistors with the localized widenings extending beyond the boundaries of the contacts. The patterned spaces with localized widenings can be filled with polysilicon for WLs to the memory cells.

Variations can include forming the first localized widening by forming a pattern of dielectric lines spaced apart from each other and forming a layer of dielectric material on the pattern of dielectric lines, where the layer has a pattern of openings. Portions of the layer of material and portions of the dielectric lines can be removed such that a pattern of spaces having localized widenings is formed in the pattern of dielectric lines. The spaces can be filled with metal for DLs to the memory cells with the metal filling the localized widenings contacting DL contacts to the memory cells. Similarly or alternatively, forming a pattern of dielectric lines and forming a layer of dielectric material on the pattern of dielectric lines, where the layer has a pattern of openings, can be processed to generate spaces with localized widenings of the spaces made at locations of contacts to gates of transistors with the localized widenings extending beyond the boundaries of the contacts. The patterned spaces with localized widenings can be filled with polysilicon for WLs to the memory cells.

Variations can include the first localized widening of the DL formed having a range of 1.5 times to 2.5 times a width of the DL between the DL contact and a directly adjacent DL contact to which the DL is arranged. Variations can include the second localized widening of the WL formed having a range of 1.5 times to 2.5 times a width of the WL between the gate contact and a directly adjacent gate contact to which the WL is arranged.

Variations can include variations in the material used in the materials associated with the WL and the digit line. The WL can be formed as a polysilicon access line. The DL can be formed as a metal line, where the metal can be, but is not limited to, one or more of tungsten, molybdenum, or ruthenium. The metal DL can be formed on and contacting a DL contact to a memory cell of an array, where the DL can include, but is not limited to, one or more of titanium, titanium nitride, tungsten nitride, tungsten silicide, or tungsten silicide nitride.

Variations can include variations in the method of forming the digit line. A damascene DL can be formed using chemical vapor deposition, plasma-enhance chemical vapor deposition, or atomic layer deposition. A DL can be formed in a subtractive process flow using physical vapor deposition, chemical vapor deposition, plasma-enhance chemical vapor deposition, or atomic layer deposition.

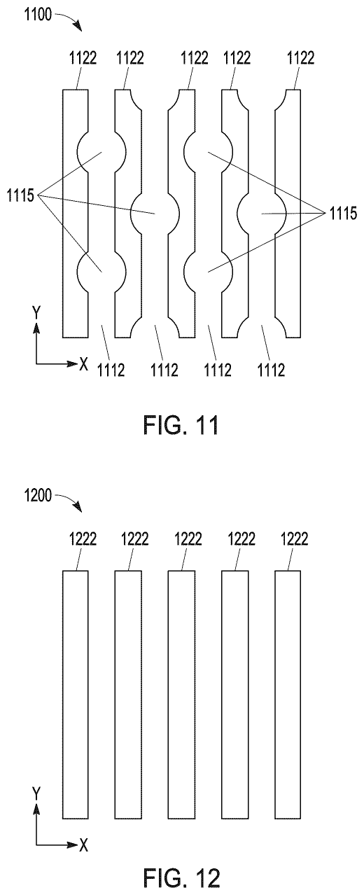

FIG. 11 illustrates an embodiment of an example structure 1100 in a process flow to generate a bubble pattern for DLs of a memory device. Structure 1100 has been generated by a direct print procedure. Dielectric material 1122 has been direct printed with a pattern of open lines 1112 having bubbles 1115 in each open line 1112. Open lines 1112 can be spaced apart from each other according to the parameters of the direct print. Bubbles 1115 can be located above DL contacts of the memory device. Other localized widenings can be generated having a shape different from the shape of bubbles 1115. Open lines 1112 can be filled with metal for DLs to the memory cells. The number of bubbles in each open line 1112 can depend on the number of memory cells to be coupled to by filling the open line 1112 to construct a DL.

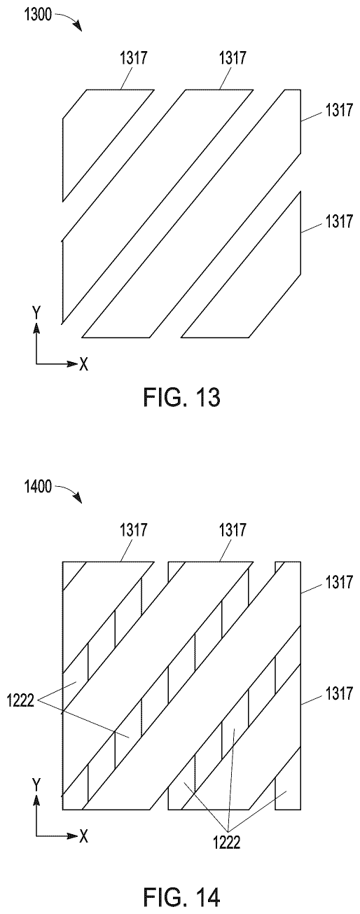

FIGS. 12-15 illustrate an embodiment of an example process flow to generate a bubble pattern for DLs of a memory device. FIG. 12 shows a structure 1200 having a pattern of first dielectric lines 1222 spaced apart from each other, forming a pattern of openings (spaces). FIG. 13 shows a structure 1300 having a pattern of second dielectric lines 1317 spaced apart from each other, forming a pattern of openings (spaces). The pattern of second dielectric lines 1317 can be arranged in a direction that is different from the direction of the pattern of first dielectric lines 1222. The width of the second dielectric lines 1317 can be different from the width of the first dielectric lines 1222. The width of the spaces constructed by the second dielectric lines 1317 can be different from the width of the spaces constructed by the first dielectric lines 1222.

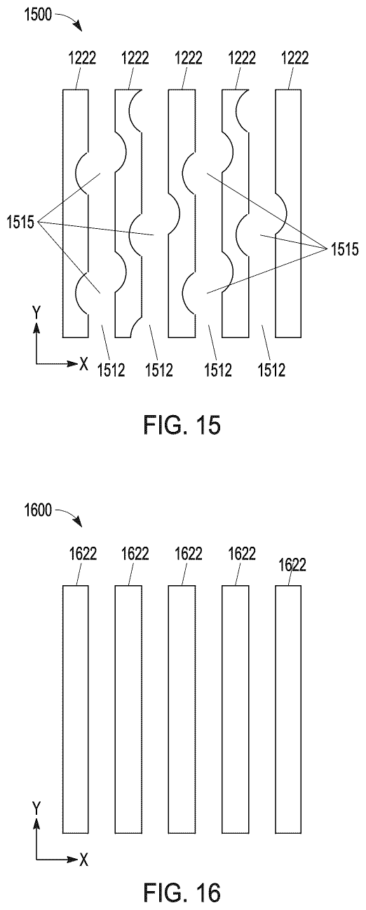

FIG. 14 shows a structure 1400 generated by forming the pattern of second dielectric lines 1317 of structure 1300 of FIG. 13 on the pattern of first dielectric lines 1222 of structure 1200 of FIG. 12. FIG. 15 shows a structure 1500 generated by processing structure 1400 of FIG. 14. Structure 1500 has been formed by removing second dielectric lines 1317 in a manner that provides spaces 1512 between the first dielectric lines 1222 locally widened to form bubbles 1515 along the first dielectric lines 1222. Other localized widenings can be generated having a shape different from the shape of bubbles 1515. Spaces 1512 can be filled with metal for DLs to the memory cells of the memory device. The number of bubbles in each space 1512 can depend on the number of memory cells to be coupled to by filling space 1512 to construct a DL.

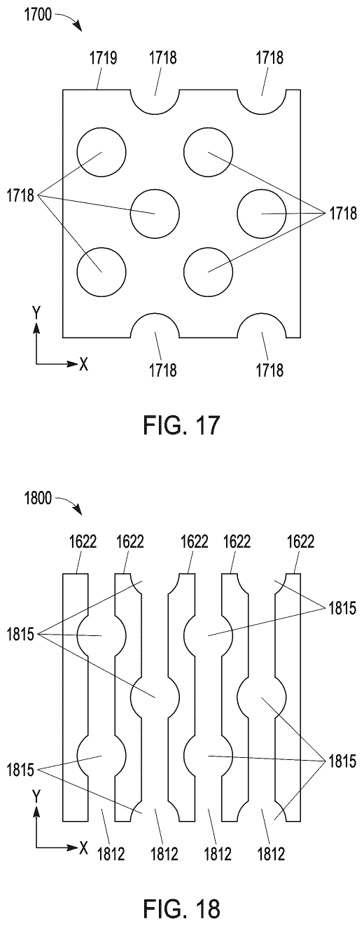

FIGS. 16-18 illustrate an embodiment of an process flow to generate a bubble pattern for DLs of a memory device. FIG. 16 shows a structure 1600 having a pattern of dielectric lines 1622 spaced apart from each other, forming a pattern of openings (spaces). FIG. 17 shows a structure 1700 having a layer 1719 of dielectric material having a pattern of openings 1718. FIG. 18 shows an example of processing structure 1700 of FIG. 17 and structure 1600 of FIG. 16. Structure 1700 has been formed on structure 1600. Portions of layer 1719 of dielectric material and portions of dielectric lines 1622 have been removed. The removal process has provided a pattern of spaces 1812 having localized widenings formed as bubbles 1815 in the pattern of dielectric lines 1622. Removal of the portions of layer 1719 can be a complete removal or portions of layer 1719 can remain on dielectric lines 1622 at locations on dielectric lines 1622 separate from bubbles 1815. Other localized widenings can be generated having a shape different from the shape of bubbles 1815. Spaces 1812 can be filled with metal for DLs to the memory cells of the memory device. The number of bubbles in each space 1812 can depend on the number of memory cells to be coupled to by filling spaces 1812 to construct a DL.

Example process flows for constructing DLs with localized widening have been illustrated by the direct print process of FIG. 11, the trim line/space pattern processing with a second line/space pattern of FIGS. 12-15, and the merge line with space pattern of FIGS. 16-18. Others process flows can be implemented using merging patterns and pitch multiplication. Pitch, as used herein, is the distance between specified identical points in features at least at two adjacent locations. Pitch multiplication is a process of multiplying one pitch class set with another, with the resultant product being a superset of pitch classes. The bubble DL flow process or other localized widening process discussed above for damascene process flow may be applied to a subtractive DL formation as well for other similar parameter optimizations based on relative separation distances. However, the location of the bubble and optimized length and width may be different. Focus above has been on damascene DL as relevant metal processes for damascene DL formation may have higher resistivity, where optimizable processing may be an enhancement. Additionally, such localized widening can be applied to WL formation.

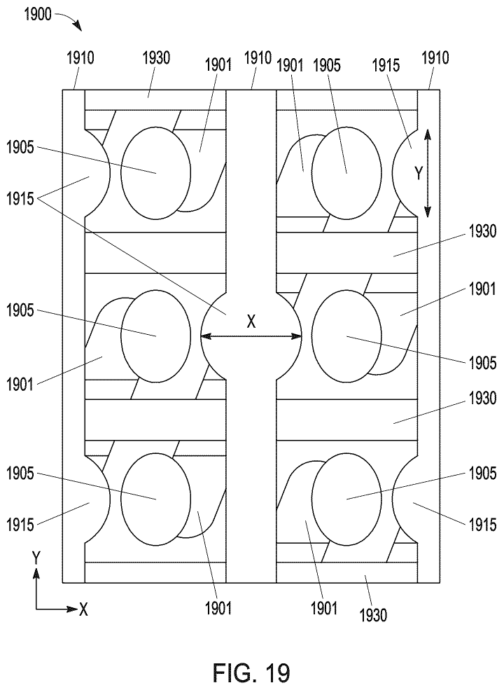

FIG. 19 is a representation of a memory device 1900 including DLs 1910 having localized widening over DL contacts to memory cells in an array of memory device 1900. The localized widening can be realized by bubbles 1915 having a width x and a length y. The DL contacts are not shown as they are under bubbles 1915. DLs 1910 can be damascene DLs.

Memory device 1900 can also include WLs 1930 and active areas 1901 of the memory cells. CCONs 1905 can be coupled to active areas 1901. The representation in FIG. 19 is a top view with isolation regions not shown to focus on the relationship of DLs 1910, WLs 1930, active areas 1901, and CCONs 1905, where one or more of these components can be on a different plane than other components. The components can include the materials of the structure 100 of FIG. 1. The localized widening of DLs can be in a range of 1.5 times to 2.5 times a width of a DL 1910, outside the localized widenings, between a DL contact and a directly adjacent DL contact on which the DL is coupled. Increasing bubble length y and width x can reduce overall DL resistance.

In various embodiments, a memory device can include an array of memory cells and a WL coupled to a gate contact to a memory cell of the array, where the WL has a localized widening about the gate contact. The localized widening about the gate contact can have a bubble shape. The WL can include polysilicon. The gate contact can include one or more of titanium, titanium nitride, tungsten nitride, tungsten silicide, or tungsten silicide nitride. The localized widening of the WL can be in a range of 1.5 times to 2.5 times a width of the WL, outside the localized widening, between the gate contact and a directly adjacent gate contact to which the WL is coupled.

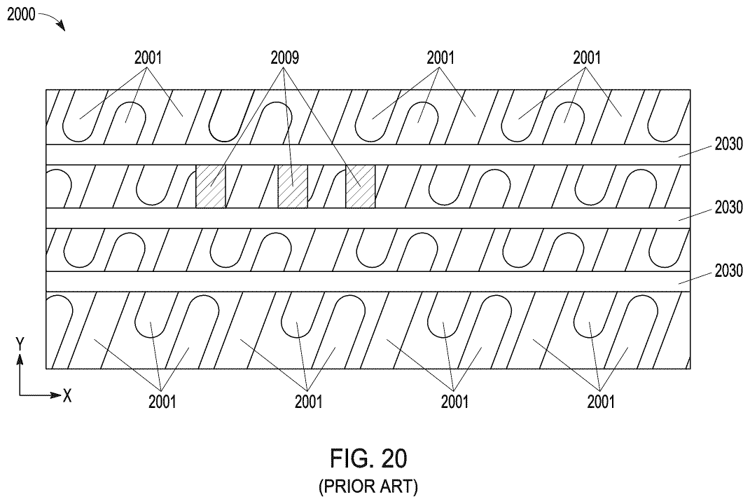

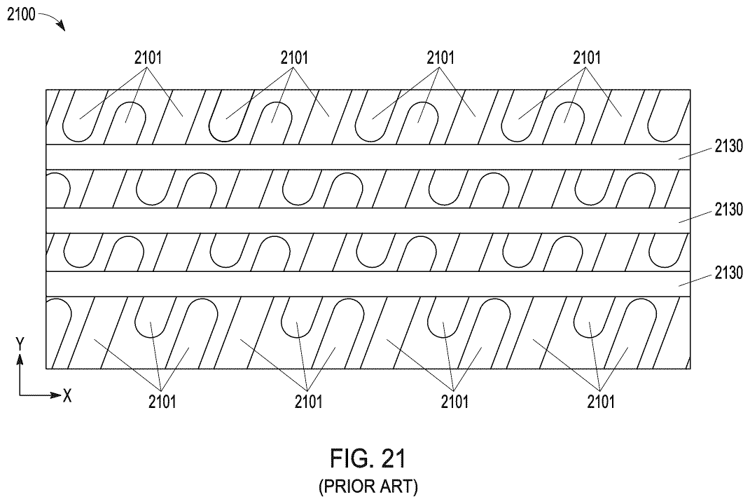

FIGS. 20-22 illustrate three configurations of WLs for a memory device. FIG. 20 illustrates structure 2000 having a configuration of straight WLs 2030 with respect to active areas 2001. Each WL 2030 can have a small width arranged with relatively large CCON pads 2009. Such a configuration provides a structure to avoid toppling of WLs 2030. However, configuration may result in poor WL resistance.

FIG. 21 illustrates a structure 2100 having a configuration of straight WLs 2130 with respect to active areas 2101. Each WL 2130 can have a width larger than the width of DLs 2020 of FIG. 20. Such a configuration can provide a trade-off between WL resistance and resistance to toppling.

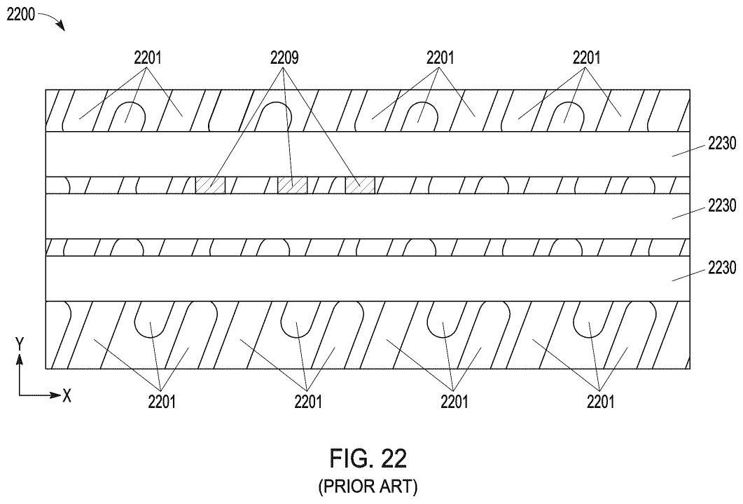

FIG. 22 illustrates a structure 2200 having a configuration of straight WLs 2230 with respect to active areas 2201. Each WL 2230 can have a large width arranged with relatively narrow CCON pads 2209 compared to CCON pads 2009 of structure 2000 of FIG. 20. Such a configuration provides enhanced WL resistance properties compared to WLs 2030 of structure 2000 and WLs 2130 of structure 2100. However, the configuration may result in susceptibility to toppling of WLs 2230.

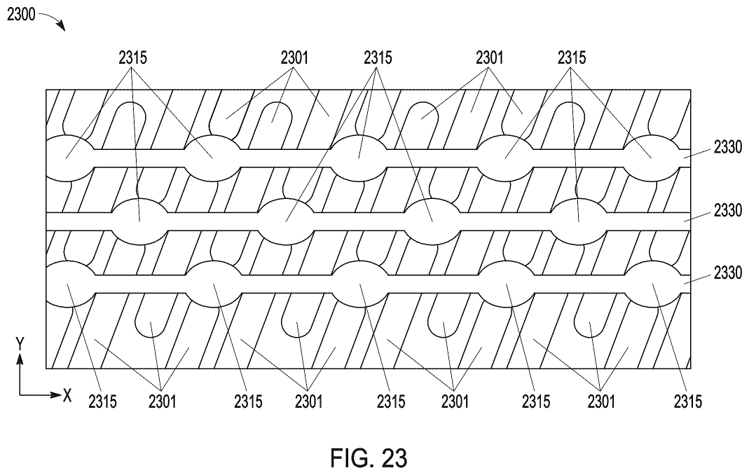

FIG. 23 illustrates a structure 2300 including a configuration of WLs 2230 having localized widenings 2315 over gate contacts with respect to active areas 2301. Localize widenings 2315 can be realized, but not limited to, bubble-like structures. WLs 2230 having localized widenings 2315 can be formed in a manner similar to the manner in which DLs with localized widenings are formed as taught herein,

Various deposition techniques for components of structures 100-900 and 1100-2300 in the process flow of FIGS. 11-18 can be used that are typical for the material being formed, the dimensions of the material being formed, and the architecture in which the material is being formed. Selective etching can be used to remove selected regions in some of the processing discussed herein. Selective etching is a process in which one or more materials are removed from a structure, while one or more other materials remain in the structure with no or little removal. Selective etching can depend on the material to be etched, the material not to be etched, the etchant employed, and the method for etching. Types of etching can include wet etching and dry etching, where each of these two basic methods can include a number of different etching procedures. In addition, conventional masking techniques, providing protective regions in the processing, can be used in removal of selected regions in forming DLs with localized widening in a memory device.

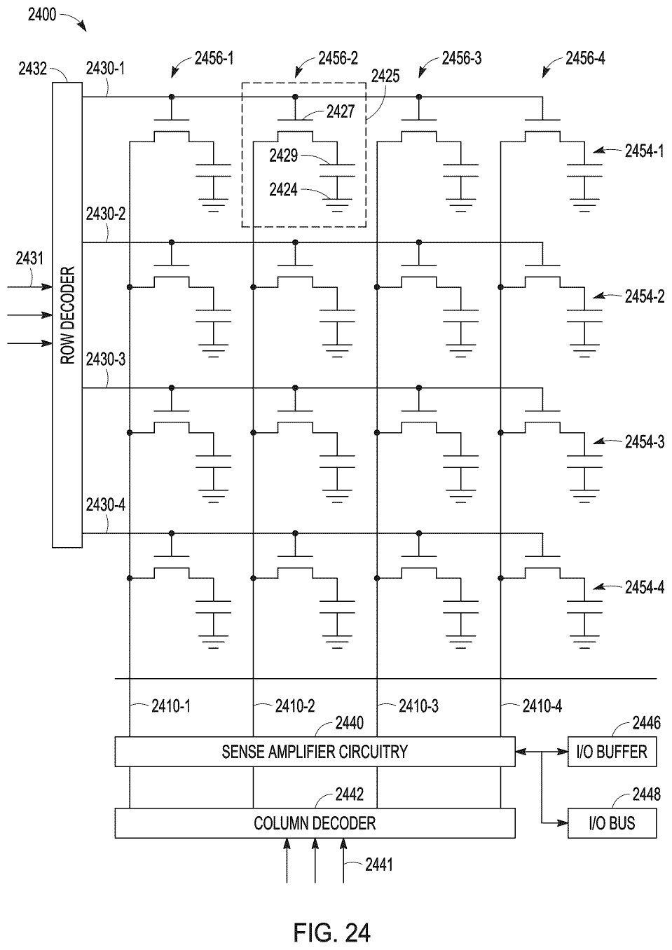

FIG. 24 is a schematic of an embodiment of an example DRAM device 2400 that can include an architecture including DLs having localized widenings about DL contacts to access transistors of memory cells of a memory array of DRAM device 2400. DRAM device 2400 can include an array of memory cells 2425 (only one being labeled in FIG. 24 for case of presentation) arranged in rows 2454-1, 2454-2, 2454-3, and 2454-4 and columns 2456-1, 2456-2, 2456-3, and 2456-4. For simplicity and case of discussion, the array is shown in only two dimensions, but the array can be extended into the third dimension. Further, while only four rows 2454-1, 2454-2, 2454-3, and 2454-4 and four columns 2456-1, 2456-2, 2456-3, and 2456-4 of four memory cells are illustrated, DRAM devices like DRAM device 2400 can have significantly more memory cells 2425 (e.g., tens, hundreds, or thousands of memory cells) per row or per column.

Each memory cell 2425 can include a single transistor 2427 and a single capacitor 2429, which is commonly referred to as a 1T1C (one-transistor-one capacitor cell). One plate of capacitor 2429, which can be termed the “node plate,” is connected to the drain terminal of transistor 2427, whereas the other plate of the capacitor 2429 is connected to a reference 2424, which can be ground. Each capacitor 2429 within the array of 1T1C memory cells 2425 typically serves to store one bit of data, and the respective transistor 2427 serves as an access device to write to or read from storage capacitor 2429.

The transistor gate terminals within each row of rows 2454-1, 2454-2, 2454-3, and 2454-4 arc portions of respective WLs 2430-1, 2430-2, 2430-3, and 2430-4 (for example, word lines), and the transistor source terminals within each of columns 2456-1, 2456-2, 2456-3, and 2456-4 are electrically connected to respective DLs 2410-1, 2410-2, 2410-3, and 2410-4 (for example bit lines). A row decoder 2432 can selectively drive the individual WLs 2430-1, 2430-2, 2430-3, and 2430-4, responsive to row address signals 2431 input to row decoder 2432. Driving a given WL at a high voltage causes the access transistors within the respective row to conduct, thereby connecting the storage capacitors within the row to the respective DLs, such that charge can be transferred between the DLs and the storage capacitors for read or write operations. Both read and write operations can be performed via sense amplifier circuitry 2440, which can transfer bit values between the memory cells 2425 of the selected row of the rows 2454-1, 2454-2, 2454-3, and 2454-4 and input/output buffers 2446 (for write/read operations) or external input/output data buses 2448.

A column decoder 2442 responsive to column address signals 2441 can select which of the memory cells 2425 within the selected row is read out or written to. Alternatively, for read operations, the storage capacitors 2429 within the selected row may be read out simultaneously and latched, and the column decoder 2442 can then select which latch bits to connect to the output data bus 2448. Since read-out of the storage capacitors destroys the stored information, the read operation is accompanied by a simultaneous rewrite of the capacitor charge. Further, in between read/write operations, the capacitor charge is repeatedly refreshed to prevent data loss. Details of read/rewrite, write, and refresh operations are well-known to those of ordinary skill in the art.

DLs 2410-1, 2410-2, 2410-3, and 2410-4 can be constructed as metal DLs having localized widenings about DL contacts to access transistors 1027 of memory cells 1025 of a memory array of DRAM device 2400, as taught herein. The metal can be the same for DLs 2410-1, 2410-2, 2410-3, and 2410-4 and the metal contacts to these DLs and can be formed at the same portion of the fabrication process flow.

DRAM device 2400 may be implemented as an integrated circuit within a package that includes pins for receiving supply voltages (e.g., to provide the source and gate voltages for the transistors 2427) and signals (including data, address, and control signals). FIG. 24 depicts DRAM device 2400 in simplified form to illustrate basic structural components, omitting many details of the memory cells 2425 and associated WLs 2430-1, 2430-2, 2430-3, and 2430-4 and DLs 2410-1, 2410-2, 2410-3, and 2410-4 as well as the peripheral circuitry. For example, in addition to the row decoder 2432 and column decoder 2442, sense amplifier circuitry 2440, and buffers 2446, DRAM device 2400 may include further peripheral circuitry, such as a memory control unit that controls the memory operations based on control signals (provided, e.g., by an external processor), additional input/output circuitry, etc. Details of such peripheral circuitry are generally known to those of ordinary skill in the art and not further discussed herein.

Electronic devices can be broken down into several main components: a processor (e.g., a central processing unit (CPU) or other main processor); memory (e.g., one or more volatile or non-volatile RAM memory device, such as DRAM, mobile or low-power double-data-rate synchronous DRAM (DDR SDRAM), etc.); and a storage device (e.g., non-volatile memory (NVM) device, such as flash memory, ROM, a solid-state drive (SSD), a MultiMediaCard (MMC), or other memory card structure or assembly, etc.). Electronic devices, such as mobile electronic devices (e.g., smart phones, tablets, etc.), electronic devices for use in automotive applications (e.g., automotive sensors, control units, driver-assistance systems, passenger safety or comfort systems, etc.), and internet-connected appliances or devices (e.g., Internet-of-Things (IoT) devices, etc.), have varying storage needs depending on, among other things, the type of electronic device, use environment, performance expectations, etc. In certain examples, electronic devices can include a user interface (e.g., a display, touch-screen, keyboard, one or more buttons, etc.), a graphics processing unit (GPU), a power management circuit, a baseband processor or one or more transceiver circuits, etc. As used herein, “processor device” means any type of computational circuit such as, but not limited to, a microprocessor, a microcontroller, a graphics processor, a digital signal processor (DSP), or any other type of processor or processing circuit, including a group of processors or multi-core devices.

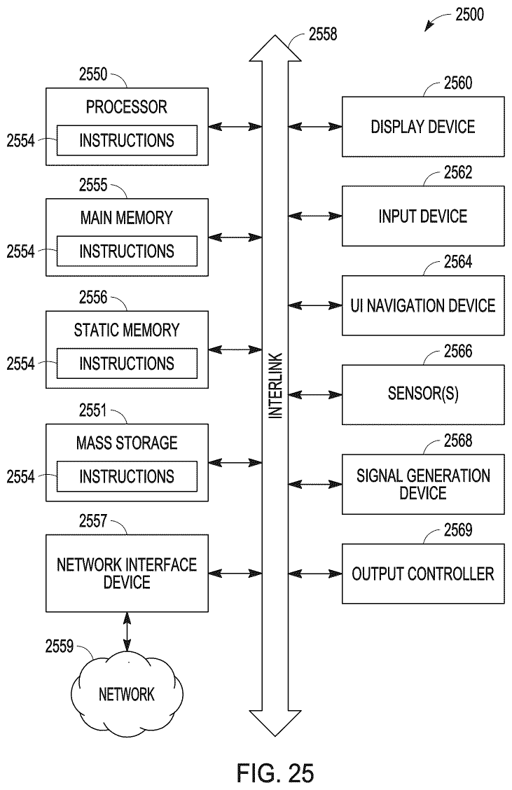

FIG. 25 illustrates a block diagram of an example machine 2500 having one or more embodiments of memory components discussed herein. In alternative embodiments, machine 2500 may operate as a standalone device or may be connected (e.g., networked) to other machines. In a networked deployment, machine 2500 may operate in the capacity of a server machine, a client machine, or both in server-client network environments. In an example, machine 2500 may act as a peer machine in peer-to-peer (P2P) (or other distributed) network environment. Machine 2500 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform one or more of methodologies such as, but not limited to, cloud computing, software as a service (SaaS), or other computer cluster configurations. Example machine 2500 can include one or more memory devices having structures as discussed with respect to structure 100 of FIG. 1.

Machine (e.g., computer system) 2500 may include a hardware processor 2550 (e.g., a CPU, a GPU, a hardware processor core, or any combination thereof), a main memory 2555 and a static memory 2556, some or all of which may communicate with each other via an interlink (e.g., bus) 2558. Machine 2500 may further include a display device 2560, an alphanumeric input device 2562 (e.g., a keyboard), and a user interface (UI) navigation device 2564 (e.g., a mouse). In an example, display device 2560, alphanumeric input device 2562, and UI navigation device 2564 may be a touch screen display. Machine 2500 may additionally include a mass storage (e.g., drive unit) 2551, a signal generation device 2568 (e.g., a speaker), a network interface device 2557, and one or more sensors 2566, such as a global positioning system (GPS) sensor, compass, accelerometer, or other sensor. Machine 2500 may include an output controller 2569, such as a serial (e.g., USB, parallel, or other wired or wireless (e.g., infrared (IR), near field communication (NFC), etc.) connection to communicate or control one or more peripheral devices (e.g., a printer, card reader, etc.).

Machine 2500 may include a machine-readable medium on which is stored one or more sets of data structures or instructions 2554 (for example, software or microcode) embodying or utilized by machine 2500. Instructions 2554 may also reside, completely or at least partially, within main memory 2555, within static memory 2556, within mass storage 2551, or within hardware processor 2550 during execution thereof by machine 2500. In an example, one or any combination of hardware processor 2550, main memory 2555, static memory 2556, or mass storage 2551 may constitute machine-readable medium. Machine-readable medium can be a single medium or multiple media (e.g., a centralized or distributed database, or associated caches and servers) configured to store one or more instructions 2554.

The term “machine-readable medium” may include any medium that is capable of storing instructions for execution by machine 2500 and that cause machine 2500 to perform any one or more of the techniques for which machine 2500 is implemented. Non-limiting machine-readable medium examples may include solid-state memories, and optical and magnetic media. Non-volatile machine-readable medium may include semiconductor memory devices such as EPROM, EEPROM, and flash memory devices; magnetic disks, such as internal hard disks and removable disks; magneto-optical disks; and compact disc-ROM (CD-ROM) and digital versatile disc-read only memory (DVD-ROM) disks. Volatile machine-readable medium may include (RAM), DRAM, SRAM, or SDRAM.

Instructions 2554 (e.g., software, programs, microcode, an operating system (OS), etc.) or other data stored on mass storage 2551, can be accessed by main memory 2555 for use by processor 2550. Main memory 2555 (e.g., DRAM) is typically fast, but volatile, and thus a different type of storage than mass storage 2551 (e.g., an SSD), which is suitable for long-term storage, including while in an “off” condition. Instructions 2554 or data in use by a user or machine 2500 are typically loaded in main memory 2555 for use by processor 2550. When main memory 2555 is full, virtual space from mass storage 2551 can be allocated to supplement main memory 2555; however, because mass storage 2551 is typically slower than main memory 2555, and write speeds are typically at least twice as slow as read speeds, use of virtual memory can greatly reduce user experience due to storage device latency (in contrast to main memory 2555, e.g., DRAM). Further, use of mass storage 2551 for virtual memory can greatly reduce the usable lifespan of mass storage 2551.

Storage devices optimized for mobile electronic devices, or mobile storage, traditionally include MMC solid-state storage devices (e.g., micro Secure Digital (microSD™) cards, etc.). MMC devices include a number of parallel interfaces (e.g., an 8-bit parallel interface) with a host device and are often removable and separate components from the host device. In contrast, eMMC™ devices are attached to a circuit board and considered a component of the host device, with read speeds that rival SATA based SSD devices. However, demand for mobile device performance continues to increase, such as to fully enable virtual or augmented-reality devices, utilize increasing networks speeds, etc. In response to this demand, storage devices have shifted from parallel to serial communication interfaces. UFS devices, including controllers and firmware, communicate with a host device using a low-voltage differential signaling (LVDS) serial interface with dedicated read/write paths, further advancing greater read/write speeds.

Instructions 2554 may further be transmitted or received over a network 2559 using a transmission medium via network interface device 2557 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, network interface device 2557 may include one or more physical jacks (e.g., Ethernet, coaxial, or phone jacks) or one or more antennas to connect to the communications network 2526. In an example, network interface device 2557 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible medium that is capable of transporting instructions for execution by machine 2500 or data to or from machine 2500. The transportation can include using digital or analog communications signals that can be transmitted over the transmission medium to facilitate communication of such software or data.

The following are example embodiments of devices and methods, in accordance with the teachings herein.

An example memory device 1 can comprise an array of memory cells; a DL contact coupled to a memory cell of the array; and a DL arranged on the DL contact, the DL having a localized widening about the DL contact.

An example memory device 2 can include features of example memory device 1 and can include the DL to include one or more of tungsten, molybdenum, or ruthenium.

An example memory device 3 can include features of any of the preceding example memory devices and can include the DL contact to include one or more of titanium, titanium nitride, tungsten nitride, tungsten silicide, or tungsten silicide nitride.

An example memory device 4 can include features of any of the preceding example memory devices and can include the localized widening of the DL being in a range of 1.5 times to 2.5 times a width of the DL between the DL contact and a directly adjacent DL contact on which the DL is coupled.

An example memory device 5 can include features of any of the preceding example memory devices and can include the localized widening about the DL contact having a bubble shape.

An example memory device 6 can include features of any of the preceding example memory devices and can include the DL being a damascene digit line.

In an example memory device 7, any of the memory devices of example memory devices 1 to 6 may include memory devices incorporated into an electronic apparatus further comprising a host processor or memory controller and a communication bus extending between the host processor/memory controller and the memory device.

In an example memory device 8, any of the memory devices of example memory devices 1 to 7 may be modified to include any structure presented in another of example memory device 1 to 7.

In an example memory device 9, any apparatus associated with the memory devices of example memory devices 1 to 8 may further include a machine-readable storage device configured to store instructions as a physical state, wherein the instructions may be used to perform one or more operations of the apparatus.

In an example memory device 10, any of the memory devices of example memory devices 1 to 9 may be operated in accordance with any of the below example methods 1 to 13.

An example memory device 11 can comprise an array of memory cells; and an WL coupled to a gate contact to a memory cell of the array, the WL having a localized widening about the gate contact.

An example memory device 12 can include features of example memory device 11 and can include the WL to include polysilicon.

An example memory device 13 can include features of any of the preceding example memory devices 11 to 12 and can include the gate contact to include one or more of titanium, titanium nitride, tungsten nitride, tungsten silicide, or tungsten silicide nitride.

An example memory device 14 can include features of any of the preceding example memory devices 11 to 13 and can include the localized widening of the WL being in a range of 1.5 times to 2.5 times a width of the WL between the gate contact and a directly adjacent gate contact to which the WL is coupled.

An example memory device 15 can include features of any of the preceding example memory devices 11 to 14 and can include the localized widening about the gate contact having a bubble shape.

In an example memory device 16, any of the memory devices of example memory devices 11 to 15 may include memory devices incorporated into an electronic apparatus further comprising a host processor or memory controller and a communication bus extending between the host processor/memory controller and the memory device.

In an example memory device 17, any of the memory devices of example memory devices 11 to 16 may be modified to include any structure presented in another of example memory device 11 to 16.

In an example memory device 18, any apparatus associated with the memory devices of example memory devices 11 to 17 may further include a machine-readable storage device configured to store instructions as a physical state, wherein the instructions may be used to perform one or more operations of the apparatus.

In an example memory device 19, any of the memory devices of example memory devices 11 to 18 may be operated in accordance with any of the below example methods 1 to 13.

An example memory device 20 can include features of any of the preceding example memory devices 1 to 19.

An example method 1 of forming a memory device can comprise forming an array of memory cells; and forming a DL coupled to a DL contact to a memory cell of the array with the DL having a first localized widening about the DL contact, or forming an WL coupled to a gate contact to the memory cell of the array with the WL having a second localized widening about the gate contact.

An example method 2 of forming a memory device can include features of example method 1 of forming a memory device and can include forming the first localized widening includes direct printing a dielectric material with a pattern of open lines having localized widenings in each open line spaced apart in the respective open line; and filling the open lines with metal for DLs to the memory cells.

An example method 3 of forming a memory device can include features of any of the preceding example methods of forming a memory device and can include forming the first localized widening to include: forming a pattern of first dielectric lines spaced apart from each other; forming a pattern of second dielectric lines on the pattern of first dielectric lines, the second dielectric lines spaced apart from each other; removing the second dielectric lines such that spaces between the first dielectric lines have localized widenings along the first dielectric lines; and filling the spaces with metal for DLs to the memory cells.

An example method 4 of forming a memory device can include features of any of the preceding example methods of forming a memory device and can include forming the first localized widening to include: forming a pattern of dielectric lines spaced apart from each other; forming a layer of dielectric material on the pattern of dielectric lines, the layer having a pattern of openings; removing portions of the layer of material and portions of the dielectric lines such that a pattern of spaces having localized widenings are formed in the pattern of dielectric lines; and filling the spaces with metal for DLs to the memory cells.

An example method 5 of forming a memory device can include features of any of the preceding example methods of forming a memory device and can include forming the second localized widening of the WL to include forming the second localized widening having a range of 1.5 times to 2.5 times a width of the WL between the gate contact and a directly adjacent gate contact to which the WL is arranged.

An example method 6 of forming a memory device can include features of any of the preceding example methods of forming a memory device and can include forming the first localized widening of the DL to include forming the first localized widening in a range of 1.5 times to 2.5 times a width of the DL between the DL contact and a directly adjacent DL contact to which the DL is arranged.

An example method 7 of forming a memory device can include features of any of the preceding example methods of forming a memory device and can include forming the WL to include forming a polysilicon access line.

An example method 8 of forming a memory device can include features of any of the preceding example methods of forming a memory device and can include forming the DL to include forming a damascene DL using chemical vapor deposition, plasma-enhanced chemical vapor deposition, or atomic layer deposition.

An example method 9 of forming a memory device can include features of any of the preceding example methods of forming a memory device and can include forming the DL to include forming the DL in a subtractive process flow using physical vapor deposition, chemical vapor deposition, plasma-enhanced chemical vapor deposition, or atomic layer deposition.

In an example method 10, any of the example methods 1 to 9 of forming a memory device may be performed in forming an electronic apparatus further comprising a host processor and a communication bus extending between the host processor and a memory system.

In an example method 11 of forming a memory device, any of the example methods 1 to 10 of forming a memory device may be modified to include operations set forth in any other of example methods 1 to 10.

In an example method 12 of forming a memory device, any of the example methods 1 to 11 of forming a memory device may be implemented at least in part through use of instructions stored as a physical state in one or more machine-readable storage devices.

An example method 13 of forming a memory device can include features of any of the preceding example methods 1 to 12 of forming a memory device and can include performing functions associated with any features of example memory devices 1 to 20.

An example machine-readable storage device storing instructions, that when executed by one or more processors, cause a machine to perform operations, can comprise instructions to perform functions associated with any features of example memory devices 1 to 20 or perform form methods associated with any features of example methods 1 to 13 of forming a memory device.

Although specific embodiments have been illustrated and described herein, it will be appreciated by those of ordinary skill in the art that any arrangement that is calculated to achieve the same purpose may be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A memory device comprising:
an array of memory cells;
a digit line contact coupled to a memory cell of the array; and
a digit line arranged on the digit line contact, the digit line having a localized widening about the digit line contact.

2. The memory device of claim 1, wherein the digit line includes one or more of tungsten, molybdenum, or ruthenium.

3. The memory device of claim 1, wherein the digit line contact includes one or more of titanium, titanium nitride, tungsten nitride, tungsten silicide, or tungsten silicide nitride.

4. The memory device of claim 1, wherein the localized widening of the digit line is in a range of 1.5 times to 2.5 times a width of the digit line between the digit line contact and a directly adjacent digit line contact on which the digit line is coupled.

5. The memory device of claim 1, wherein the localized widening about the digit line contact has a bubble shape.

6. The memory device of claim 1, wherein the digit line is a damascene digit line.

7. A memory device comprising:
an array of memory cells; and
an access line coupled to a gate contact to a memory cell of the array, the access line having a localized widening about the gate contact.

8. The memory device of claim 7, wherein the access line includes polysilicon.

9. The memory device of claim 7, wherein the gate contact includes one or more of titanium, titanium nitride, tungsten nitride, tungsten silicide, or tungsten silicide nitride.

10. The memory device of claim 7, wherein the localized widening of the access line is in a range of 1.5 times to 2.5 times a width of the access line between the gate contact and a directly adjacent gate contact to which the access line is coupled.

11. The memory device of claim 7, wherein the localized widening about the gate contact has a bubble shape.

12. A method of forming a memory device comprising:
forming an array of memory cells; and
forming a digit line coupled to a digit line contact to a memory cell of the array with the digit line having a first localized widening about the digit line contact, or forming an access line coupled to a gate contact to the memory cell of the array with the access line having a second localized widening about the gate contact.

13. The method of claim 12, wherein forming the first localized widening includes:
direct printing a dielectric material with a pattern of open lines having localized widenings in each open line spaced apart in the respective open line; and
filling the open lines with metal for digit lines to the memory cells.

14. The method of claim 12, wherein forming the first localized widening includes:
forming a pattern of first dielectric lines spaced apart from each other;
forming a pattern of second dielectric lines on the pattern of first dielectric lines, the second dielectric lines spaced apart from each other;
removing the second dielectric lines such that spaces between the first dielectric lines have localized widenings along the first dielectric lines; and
filling the spaces with metal for digit lines to the memory cells.

15. The method of claim 12, wherein forming the first localized widening includes:
forming a pattern of dielectric lines spaced apart from each other;
forming a layer of dielectric material on the pattern of dielectric lines, the layer having a pattern of openings;
removing portions of the layer of material and portions of the dielectric lines such that a pattern of spaces having localized widenings are formed in the pattern of dielectric lines; and
filling the spaces with metal for digit lines to the memory cells.

16. The method of claim 12, wherein forming the second localized widening of the access line includes forming the second localized widening having a range of 1.5 times to 2.5 times a width of the access line between the gate contact and a directly adjacent gate contact to which the access line is arranged.

17. The method of claim 12, wherein forming the first localized widening of the digit line includes forming the first localized widening in a range of 1.5 times to 2.5 times a width of the digit line between the digit line contact and a directly adjacent digit line contact to which the digit line is arranged.

18. The method of claim 12, wherein forming the access line includes forming a polysilicon access line.

19. The method of claim 12, wherein forming the digit line includes forming a damascene digit line using chemical vapor deposition, plasma-enhance chemical vapor deposition, or atomic layer deposition.

20. The method of claim 12, wherein forming the digit line includes forming the digit line in a subtractive process flow using physical vapor deposition, chemical vapor deposition, plasma-enhance chemical vapor deposition, or atomic layer deposition.
